(19) United States
(12) Patent Application Publication
(10) Pub. No.: US 2025/0029872 A1
(43) Pub. Date: Jan. 23, 2025

(54) METHOD FOR PRODUCING AN INTERCONNECT VIA

(71) Applicant: IMEC VZW, Leuven (BE)

(72) Inventors: Anshul Gupta, Leuven (BE); Zsolt Tokei, Leuven (BE); Stefan Decoster, Bertem (BE); Gayle Murdoch, Lubbeek (BE); Seongho Park, Heverlee (BE)

(21) Appl. No.: 18/762,318

(22) Filed: Jul. 2, 2024

(30) Foreign Application Priority Data
Jul. 20, 2023 (EP) 23186608.8

(51) Int. Cl. H01L 21/768; H01L 23/522

(52) U.S. Cl. CPC H01L 21/7682; H01L 21/76802; H01L 21/76819; H01L 21/76877; H01L 23/5226

(57) ABSTRACT

Methods and systems for producing an interconnect via are provided. A conductive layer is produced on a substrate having an upper surface of a dielectric material with conductors or contacts embedded in the dielectric material. A dielectric layer is produced on the conductive layer. An opening is formed in the dielectric layer and filled with a conductive material to form a conductive via. The dielectric layer and the via are planarized to a common planar level. At least one hardmask line which overlaps the via is formed. The dielectric material and the conductive material of the via and of the conductive layer are removed in the areas not covered by the hardmask line, resulting in a conductive line having an interconnect via on its top surface. The interconnect via is aligned to the width of the conductive line. The hardmask line is removed and a planar dielectric surface is produced.

### CROSS-REFERENCE TO RELATED APPLICATIONS

The present application is a non-provisional patent application claiming priority to European Patent Application No. EP 23186608.8, filed on Jul. 20, 2023, the contents of which are hereby incorporated by reference.

### FIELD OF THE DISCLOSURE

The present disclosure relates to the field of semiconductor processing. It relates to the formation of interconnect vias between levels of conductors of a multi-level interconnect structure of a semiconductor chip.

### BACKGROUND

Semiconductor-based integrated circuits continue to evolve towards smaller and smaller dimensions, leading to ongoing processing challenges. Multilayer conductive structures are typically built as layers of conductive lines, with interconnect vias formed between lines of the respective layers. As dimensions shrink, traditional lithography and etch processes are no longer able to ensure acceptable alignment between an interconnect via and the underlying line to which the via is connected.

A number of methods have been developed which enable self-alignment of a nano-sized interconnect via to the underlying conductive (usually metal) line. U.S. Patent Publication No. US2017256451 discloses a method wherein the metal lines of the lower level are formed by a patterning step using a hardmask in the form of a line array, and wherein the hardmask lines are maintained on the metal lines except at the via locations. At these locations, the hardmask is locally removed by lithography and selective etching to create a self-aligned via opening, which is subsequently filled by a damascene-type metal fill process. The hardmask lines are however reduced in size and/or oxidized after the metal line patterning, which can make it difficult to produce the via opening, especially at the deepest levels of a multi-level interconnect structure where the in-plane dimensions of the via opening may be in the order of a few nanometres.

Also, the remaining hardmask material is likely to increase the interlayer capacitance so there is an interest in using a hardmask material having low relative permittivity. These difficulties reduce the number of suitable choices for the hardmask material, as a material exhibiting low permittivity may not necessarily enable good etch selectivity.

### SUMMARY

The present disclosure is related to a method for producing an interconnect via for connecting a lower conductive line to an upper conductive line overlying the lower line. Throughout this description and in the claims, the term ‘conductive’ is intended to refer to ‘electrically conductive’.

The method may be used for the formation of interconnect vias which are nano-sized in three orthogonal directions, i.e. in terms of their width, length and height. The term ‘nano-sized’ in the present context is to be understood as: having at least one dimension of a few nanometres up to a few tens of nanometres. For example, a nano-sized conductive line is a line having a nano-sized width and height. A nano-sized interconnect via is a via having a nano-sized width, length and height.

In a first embodiment, a conductive layer is produced on a substrate having an upper surface formed of a dielectric material with electrical conductors or contacts embedded in the dielectric material. The substrate may for example be a process wafer whereon a FEOL portion and one or more layers of a BEOL portion have been produced according to a given layout for a number of integrated circuits arranged on the wafer. A dielectric layer is then produced on the conductive layer. An opening is formed in the dielectric layer and subsequently filled with a conductive material, after which the conductive material is planarized to the level of the dielectric material so that a conductive via is formed in the opening. This is followed by the formation of at least one hardmask line which overlaps the via so that a shoulder of the via extends on each side of the hardmask line. The dielectric material, the conductive material of the via, and of the conductive layer are then removed in the areas not covered by the hardmask line, resulting in a conductive line, having an interconnect via on its top surface. The interconnect via is formed by the removal of the shoulders of the original via, so that the interconnect via is aligned to the width of the conductive line. A second dielectric material is then produced and planarized to the top level of the hardmask line. The hardmask line and an upper portion of the second dielectric material are then removed (simultaneously or consecutively) so that a planar dielectric surface is produced with the top of the interconnect via coplanar therewith. The conductive lines of the next level of the interconnect structure can be formed on the planar surface.

In some example embodiments, a set of parallel conductive lines is formed with several self-aligned interconnect vias on one or more of the lines, the interconnect vias being produced in accordance with the method of the present disclosure. In the latter case, the second dielectric material is deposited in the spaces between the lines. In some other example embodiments, this is done in such a manner that airgaps are formed between adjacent lines.

In a second embodiment, a method for producing an interconnect via for connecting a lower electrically conductive line in a first level of a multi-level interconnect structure to an upper electrically conductive line in a second level overlying the first level is provided. The terms first level and second level refer to any two consecutive levels of the interconnect structure. The method comprises the steps of: providing a substrate having an upper surface formed of a dielectric material with electrical conductors or contacts embedded in the dielectric material, producing on the upper surface, a layer of a first conductive material and a dielectric layer formed of a first dielectric material, on the layer of the first conductive material, producing an opening in the dielectric layer, thereby exposing the first conductive material at the bottom of the opening, filling the opening with a second conductive material, which may or may not be the same as the first conductive material, planarizing the surface of the dielectric layer, thereby obtaining a conductive via embedded in the dielectric layer, wherein the upper surface of the via is coplanar with the upper surface of the dielectric layer, the upper surfaces forming a planarized surface, producing a hardmask layer on the planarized surface,
patterning the hardmask layer so as to form a hardmask line, overlapping the upper surface of the via so that a shoulder of the via extends laterally on each side of the hardmask line), removing the dielectric layer and the first and second conductive material in the areas not covered by the hardmask line), thereby obtaining a conductive line, wherein an interconnect via is formed on the conductive line by removing the shoulders of the via, so that the width of the interconnect via is aligned to the width of the conductive line, producing a layer of a second dielectric material which may or may not be the same as the first dielectric material, wherein the second dielectric material envelops the hardmask line, planarizing the layer of the second dielectric material to the top level of the hardmask line, removing the hardmask line and an upper portion of the second dielectric material, thereby producing a planar surface formed of the second dielectric material, with the interconnect via embedded therein and having a top surface coplanar with the planar surface.

According to an example embodiment, the hardmask line is one of an array of parallel lines.

According to an example embodiment, the second dielectric material is deposited in such a manner that airgaps are created between adjacent conductive lines.

According to an example embodiment, an airgap is formed on each side of the conductive line on top of which the interconnect via is formed, and the two airgaps have a top portion that overlaps a lower portion of the height of the interconnect via.

According to an example embodiment, the height (H1) of the top portion of the two airgaps is at least 50% of the height of the interconnect via.

According to an example embodiment, the interconnect via has nano-sized dimensions in three orthogonal directions.

According to an example embodiment, the height of the interconnect via is between 10 nm and 30 nm.

According to an example embodiment, the opening is filled by a bottom-up fill technique and wherein the step of planarizing the surface of the dielectric layer is done without a CMP (chemical mechanical polishing) step.

According to an example embodiment, the first and second conductive material are chosen from the group consisting of Ru, W and Mo.

According to an example embodiment, the first and second dielectric material is SiO₂ or a low-K material.

According to an example embodiment, an adhesion layer is produced on the substrate prior to forming the layer of the first conductive material, and/or wherein an adhesion layer is produced on the layer of the first conductive material, prior to forming the dielectric layer.

### BRIEF DESCRIPTION OF THE DRAWINGS

The above, as well as additional features will be better understood through the following illustrative and non-limiting detailed description, with reference to the appended drawings. In the drawings, like reference numerals will be sued for like elements unless stated otherwise.

FIG. 1 is a section of a substrate comprising a base portion, according to an example embodiment.

FIG. 2 is a section of a substrate comprising a base portion, in which the substrate has an opening, according to an example embodiment.

FIG. 3 is a section of a substrate comprising a base portion, in which the substrate has a planarized surface, according to an example embodiment.

FIG. 4 is a section of a substrate comprising a base portion, in which the substrate has a hardmask layer on a planarized surface, according to an example embodiment.

FIG. 5 is a section of a substrate comprising a base layer, in which dielectric lines have been produced, according to an example embodiment.

FIG. 6 is a section of a substrate comprising a base layer that has been subjected to an etching step, according to an example embodiment.

FIG. 7 is a section of a substrate comprising a base layer, in which a dielectric material has been produced on conductive lines of the substrate, according to an example embodiment.

FIG. 8 is a section of a substrate comprising a base layer, in which dielectric material has been planarized to expose hardmask lines, according to an example embodiment.

FIG. 9 is another view of a section of a substrate comprising a base layer, in which dielectric material has been planarized to expose hardmask lines, according to an example embodiment.

FIG. 10 is a section of a substrate comprising a base layer in which airgaps are present, according to an example embodiment.

FIG. 11 is a section of a substrate comprising a base layer in which airgaps are present and a hardmask layer has been removed, according to an example embodiment.

FIG. 12 is another view of a section of a substrate comprising a base layer in which airgaps are present, according to an example embodiment.

### DETAILED DESCRIPTION

Reference will now be made in detail to the embodiments of the present disclosure, examples of which are illustrated in the accompanying drawings. However, the following embodiments of the present disclosure may be variously modified and the range of the present disclosure is not limited by the following embodiments.

Directional terminology such as top, bottom, front, back, leading, trailing, under, over and the like in the description and the claims is used for descriptive purposes with reference to the orientation of the drawings being described, and not necessarily for describing relative positions. Because components of example embodiments can be positioned in a number of different orientations, the directional terminology is used for purposes of illustration only, and is in no way intended to be limiting, unless otherwise indicated. It is, hence, to be understood that the terms so used are interchangeable under appropriate circumstances and that the example embodiments described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices comprising only components A and B.

Reference throughout this specification to “one embodiment” or “an embodiment” means that a particular feature, structure or characteristic described in connection with the embodiment is included in at least one example embodiment. Thus, appearances of the phrases “in one embodiment” or “in an embodiment” in various places throughout this specification are not necessarily all referring to the same embodiment. Furthermore, the particular features, structures or characteristics may be combined in any suitable manner, as would be apparent to one of ordinary skill in the art from this disclosure, in one or more embodiments.

Similarly, it should be appreciated that in the description of example embodiments, various features are sometimes grouped together in a single embodiment, figure, or description thereof for the purpose of streamlining the disclosure and aiding in the understanding of one or more of the various aspects of the disclosure. This method of disclosure, however, is not to be interpreted as reflecting an intention that the example embodiment requires more features than are expressly recited in each claim. Rather, as the following claims reflect, aspects of the claims lie in less than all features of a single foregoing disclosed embodiment. Thus, the claims following the detailed description are hereby expressly incorporated into this detailed description, with each claim standing on its own as a separate example embodiment.

Furthermore, while some embodiments described herein include some but not other features included in other embodiments, combinations of features of different embodiments are meant to be within the scope of the disclosure, and form different embodiments, as would be understood by those in the art.

In the description provided herein, numerous specific details are set forth. However, it is understood that example embodiments may be practiced without these specific details. In other instances, well-known methods, structures and techniques have not been shown in detail in order not to obscure an understanding of this description.

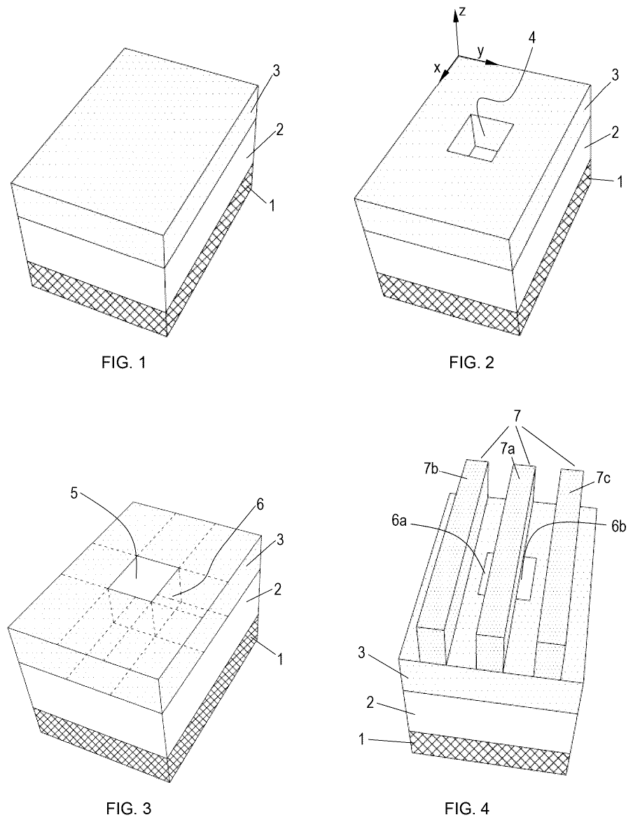

FIG. 1 shows a small section of a substrate comprising a base portion 1 which may be a nano-sized upper slice of a silicon process wafer after the front end of line (FEOL) processing and part of the back end of line (BEOL) processing. The FEOL process constitutes a sequence of processing steps for producing large numbers of semiconductor devices such as transistors and diodes on usually a silicon wafer, according to the layout of several integrated circuit chips. BEOL processing adds a multi-level interconnect structure on top of the FEOL portion of the chips, the interconnect structure comprising multiple levels of electrically conductive lines, interconnected according to a predefined interconnection scheme by vertical interconnects, referred to in the present description as ‘interconnect vias’. The interconnect levels are usually labelled Metal 0, Metal 1, Metal 2, etc (in short M₀, M₁, M₂, etc), as the line material is usually a metal such as Copper (Cu), Tungsten (W) or Ruthenium (Ru). The deepest level M₀ includes connections in direct contact with the active devices in the FEOL and is also referred to as the Middle of Line portion (MOL) of an integrated circuit.

The top surface of the base portion 1 is formed of a dielectric material, for example SiO₂ or low-K dielectric onto which surface the conductive lines of an interconnect level Mᵢ are to be formed. Embedded in the dielectric layer are electrical conductors or contacts, which may include conductive lines in level Mᵢ₋₁ or interconnect vias intended to connect the lines of level Mₓ to the lines of level Mᵢ₋₁, or connections to source or drain electrodes of transistors of the FEOL portion if level Mᵢ₋₁ is the M₀ level (MOL).

The method of the present disclosure includes method steps for forming one or more lines of any level Mᵢ and one or more interconnect vias towards the lines of level Mᵢ₊₁ for i=0, 1, 2, 3, . . . .

Two layers are produced on the top surface of the base portion 1, as illustrated in FIG. 1. The first layer 2 is a conductive layer. For the deep levels of the BEOL (for example i=1 to 3) this may for example be a layer of Ru, W or Mo. For some materials in some example embodiments, such as for Ru, an adhesion layer such as a thin TiN layer between the base substrate 1 and the Ru layer 2 may be provided.

On top of the conductive layer 2, a layer 3 of dielectric material, for example SiO₂ or a low-K dielectric, is deposited. An adhesion layer may be deposited between the conductive layer 2 and the dielectric layer 3, depending on the material of layer 2. An example embodiment is shown, however, wherein no adhesion layers are applied.

The thickness of the various layers may depend on the metallization levels to which the method is applied, i.e. the value of i. For example, for i=2 (production of interconnect vias between M₂ and M₃), the thickness of layer 2 may be in the order of 25 nm while the thickness of layer 3 may be in the order of 15 nm.

FIG. 2 is a section of a substrate comprising a base portion, in which the substrate has an opening, according to an example embodiment. With reference to FIG. 2, an opening 4 is now formed in the dielectric layer 3. A plurality of such openings may be formed simultaneously at various intended via locations across the wafer. The opening 4 is a cavity that is open to the surface of the dielectric layer 3. The opening 4 is represented as having a rectangular cross-section, but the opening may be shaped differently, for example having an ellipse-shaped or circular cross-section. For i=2, the lateral dimensions of the opening may for example be in the order of 18 nm in the x-direction and y-direction, with reference to the orthogonal axes included in FIG. 2. One method of producing openings of these dimensions is to apply a hardmask formed of a stack of SOC (spin-on-carbon), SOG (spin-on-glass) and photoresist. The photoresist is patterned to form openings which are larger than the targeted dimensions and shrink technology is applied to arrive at the desired dimensions of the opening 4. For larger values of i, i.e. at higher levels in the BEOL stack, different lithography and etch processes may be used as the lateral dimensions of the opening may be larger at those levels.

The bottom of the opening 4 is formed of the conductive material of layer 2. Therefore, in some example embodiments, if an adhesion layer is present between layer 2 and layer 3, the adhesion layer may be removed selectively with respect to the material of layer 2.

The opening 4 may be filled with a second conductive material, which may or may not be the same as the conductive material of layer 2. An additional conductive adhesion liner on the bottom of the opening 4 may be used before the opening is filled with the second material.

Filling the opening 4 may be done by a technique such as CVD (Chemical Vapour Deposition) or ALD (Atomic Layer Deposition), which may result in a thick layer of the second conductive material on top of the dielectric layer 3. This layer is then removed by grinding and CMP (chemical mechanical polishing), until a planarized surface is obtained as shown in FIG. 3: the planarized surface is formed of the dielectric material of layer 3, with an island 5 of conductive material coplanar therewith. The island 5 forms the top surface of a via 6 of conductive material that is in electrical contact with the underlying conductive layer 2. The via 6 is represented in FIG. 3 with the help of a number of auxiliary lines which help to visualize the position of the via relative to layers 2 and 3.

Another way of filling the opening 4 is by a bottom-up fill technique wherein the via 6 is built up from the bottom of the opening 4 and the via material is not deposited on the dielectric layer 3 until the opening is filled. This creates a thin layer of the conductive material on the dielectric layer 3 that may be removed by a wet etch process and without applying CMP. This approach may enable a better control of the height of the via 6.

FIG. 4 is a section of a substrate comprising a base portion, in which the substrate has a hardmask layer on a planarized surface, according to an example embodiment. With reference to FIG. 4, a hardmask layer may then be produced on the planarized surface and patterned according to a regular pattern of parallel lines 7 oriented in the x-direction. The lines of the regular pattern of parallel lines 7 may have the same width and height.

The width of the lines 7 may be smaller than the y-dimension of the island 5. For example the lines 7 may have a width and pitch of about 9 nm for i=2. As seen in FIG. 4, one line 7a is overlapping the via 6, so that lateral shoulders 6a and 6b of the via 6 extend on both sides of the line 7a without overlapping the adjacent lines 7b and 7c. As shown in FIG. 4, the lithography and etch steps applied for producing the lines 7 may be configured to produce the line 7a concentrically with respect to the y-dimension of the via 6. However, an error of 1 or 2 nm may result in a slight deviation of this theoretical case. In any case, the lines 7 are formed in such a way that two shoulders 6a and 6b of the conductive via 6 are exposed on both sides of the hardmask line 7a

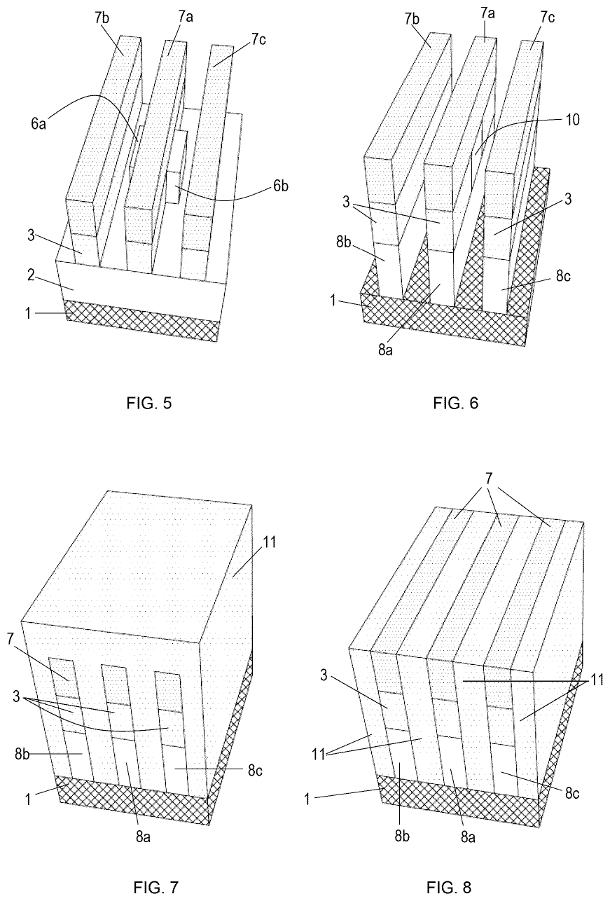

One or more etch steps are performed for transferring the hardmask line pattern to the underlying layers may then be performed. The images shown in FIGS. 5 and 6 illustrate a 2-step process, but depending on the applied materials and dimensions, a single step process may also be applicable. As seen in FIG. 5, the dielectric layer 3 is removed selectively with respect to the conductive via 6, in the areas not covered by the hardmask lines 7, resulting in dielectric lines 3 on the conductive layer 2, and the exposure of the shoulders 6a and 6b of the via 6. In a second etch step illustrated in FIG. 6, the conductive materials of the via 6 and of the underlying layer 2 are etched in the areas not covered by the hardmask lines 7, thereby creating parallel conductive lines 8a, 8b and 8c.

In the second etch step, the shoulders 6a and 6b of the conductive via 6 may be removed. What remains of the initial via 6 is an interconnect via 10 that is aligned to the width of the underlying conductive line 8a. The dielectric line 3 on top of the conductive line 8a is interrupted by the interconnect via 10.

As the initial via 6 may be formed prior to the formation of the conductive line 8a, the alignment of the interconnect via 10 to the y-dimension of the conductive line 8a may be a self-alignment. Due to the nature of the production process, the interconnect via 10 is aligned to the line 8a.

In the x-direction, the dimension of the interconnect via 10 may be the same as the x-dimension of the original via 6.

In FIGS. 5 and 6, the hardmask lines 7 are shown at their original thickness prior to the etch steps illustrated in these images, which represents an example embodiment wherein the etch selectivity is about 100%. In the example embodiments, the hardmask lines 7 may be reduced somewhat in thickness and/or become partially oxidized. These factors do not however influence the execution of the subsequent method steps according to the present disclosure. Also, the present disclosure is explained for embodiments wherein a set of parallel lines 7 is formed, which may be the case especially at the deeper BEOL levels. In some other cases, the present disclosure is theoretically applicable to a single line 7a configured to form a single conductive line with a self-aligned interconnect via formed thereon.

The remainder of the method may include the removal of the hardmask lines 7 and the embedding of the interconnect via 10 in a dielectric layer ready to produce thereon the next interconnect level. Two alternative embodiments for realizing this are described with reference respectively to FIGS. 7-9 and 10-12

FIG. 7 is a section of a substrate comprising a base layer, in which a dielectric material has been produced on conductive lines of the substrate, according to an example embodiment. With reference to FIG. 7, a dielectric material 11 is produced on the obtained conductive lines 8a-8c and the interconnect via 10. According to a first embodiment illustrated in FIG. 7, the dielectric material 11 is produced in such a way that it fills the spaces between the conductive lines 8a-8c completely and fully envelops the conductive lines 8a-8c, the dielectric lines 3 and the hardmask lines 7. The dielectric material 11 may or may not be the same material as the material of layer 3, for example SiO₂ or a low-K dielectric material

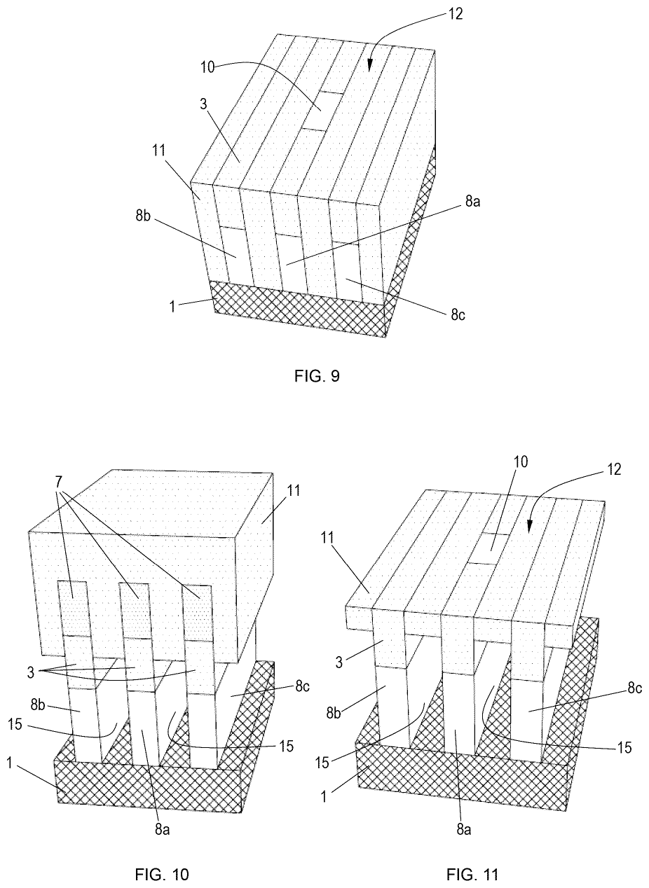

This may then be followed by planarizing the top surface of the dielectric material 11 until the hardmask lines 7 are exposed, as shown in FIG. 8, and by the removal of the hardmask lines 7 and of the dielectric material 11 between these hardmask lines, as shown in FIG. 9. The latter step may be done by a cyclic dry etch process that removes both the dielectric 11 and the hardmask material 7. In some example embodiments, no CMP is used to arrive at the image shown in FIG. 9. The hardmask material is completely removed, which may improve the avoidance of the parasitic capacitance that may be caused by the hardmask material and increase the feasibility of selecting the hardmask material only on the basis of etch-related characteristics, such as the etch selectivity relative to the materials of layers 2 and 3 and of the via 6, and the capability of simultaneously removing the hardmask lines 7 and the second dielectric material 11.

FIG. 9 is another view of a section of a substrate comprising a base layer, in which dielectric material has been planarized to expose hardmask lines, according to an example embodiment. With reference to FIG. 9, the result of the method of the present disclosure is a dielectric surface 12 with the top surface of the interconnect via 10 coplanar therewith. This surface can receive thereon a further conductive layer that is thereafter patterned to form the conductive lines of the next BEOL level Mᵢ₊₁. For i=2, this is the M₃ level. These M₃ lines may be oriented in the y-direction and have a width in the order of the x-dimension of the interconnect via 10. The production of these M₃ lines (or generally Mᵢ₊₁ lines) can be realized according to other methods.

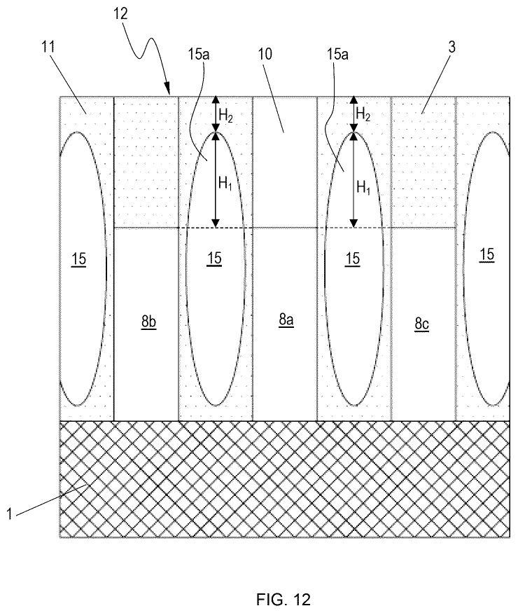

FIGS. 10 and 11 illustrate another example embodiment, according to which the dielectric material 11 is deposited in such a manner that it does not completely fill the spaces between adjacent conductive lines 8a-8c. Instead, airgaps 15 are formed. After depositing the dielectric material 11 in this way, the planarization step and the removal of the hardmask lines 7 takes place in a similar manner as described above, resulting in example embodiment shown in FIG. 11.

In FIGS. 10 and 11, the airgaps 15 are represented as though no dielectric material whatsoever is deposited beneath a given level in the z-direction, but this is merely a symbolic representation. In some example embodiments, some dielectric material is deposited on the sidewalls of the lines 8a-8c and on the substrate 1, while an air-filled cavity of the more or less ellipse-shaped cross-section remains in the spaces between the conductive lines. This more realistic representation is illustrated in a section view in FIG. 12.

In some example embodiments, the inclusion of airgaps between adjacent conductive lines may significantly reduce the capacitance of the insulation material of the interconnect structure. The methods detailed in the present disclosure may allow for airgaps to be created in higher locations than in some other methods. This is illustrated in FIG. 12: the airgaps between adjacent lines 8a/8b and 8a/8c have a top portion 15a that is directly adjacent to the interconnect via 10. This arrangement of the airgaps results in a significant reduction of the fringe capacitance between the via and neighbouring conductors in the interconnect structure. The overlap between the airgaps 15 and the interconnect via 10 is represented as the height H₁ in FIG. 12, with H₂ representing the thickness of the remaining dielectric material above the airgap 15, and with H₁+H₂ corresponding to the height of the interconnect via 10. H₂ is required to be large enough to ensure that the planarized surface 12 is homogenous. According to some example embodiments, the via height is tuned to enable H₁ to be as high as possible relative to the via height. The overlap height H₁ may be at least 50% of the via height. For example, at i=2, H₂ may be at least 5 nm, and the via height may be configured to be between 10 nm and 30 nm, so that H₁ can be 50% or up to 83% depending on the via height.

The present disclosure is applicable in the production process of any multilevel interconnect structure, such as the BEOL portion of a semiconductor chip or the back side power delivery network of a chip.

While the present disclosure has been illustrated and described in detail in the drawings and foregoing description, such illustration and description are to be considered illustrative or exemplary and not restrictive. Other variations to the disclosed embodiments can be understood and effected by those skilled in the art in practicing the claims, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used. Any reference signs in the claims should not be construed as limiting the scope.

Unless specified, the description of a layer being present, deposited or produced ‘on’ another layer or substrate, includes the options of the layer being present, produced or deposited directly on, i.e. in physical contact with, the other layer or substrate, and the layer being present, produced or deposited on one or a stack of intermediate layers between the layer and the other layer or substrate.

What is claimed is:

1. A method for producing an interconnect via for connecting a lower electrically conductive line in a first level of a multi-level interconnect structure to an upper electrically conductive line in a second level overlying the first level, the method comprising the steps of:
providing a substrate having an upper surface formed of a dielectric material with electrical conductors or contacts embedded in the dielectric material;
producing, on the upper surface, a layer of a first conductive material and a dielectric layer formed of a first dielectric material, on the layer of the first conductive material;
producing an opening in the dielectric layer, thereby exposing the first conductive material at the bottom of the opening;
filling the opening with a second conductive material, which may or may not be the same as the first conductive material;
planarizing the surface of the dielectric layer, thereby obtaining a conductive via embedded in the dielectric layer, wherein the upper surface of the via is coplanar with the upper surface of the dielectric layer, the upper surfaces forming a planarized surface;
producing a hardmask layer on the planarized surface;
patterning the hardmask layer so as to form a hardmask line, overlapping the upper surface of the via so that a shoulder of the via extends laterally on each side of the hardmask line;
removing the dielectric layer and the first and second conductive material in the areas not covered by the hardmask line, thereby obtaining a conductive line, wherein an interconnect via is formed on the conductive line by removing the shoulders of the via, so that the width of the interconnect via is aligned to the width of the conductive line;
producing a layer of a second dielectric material which may or may not be the same as the first dielectric material, wherein the second dielectric material envelops the hardmask line;
planarizing the layer of the second dielectric material to the top level of the hardmask line; and
removing the hardmask line and an upper portion of the second dielectric material, thereby producing a planar surface formed of the second dielectric material, with the interconnect via embedded therein and having a top surface coplanar with the planar surface.

2. The method according to claim 1, wherein the hardmask line is one line of an array of parallel lines.

3. The method according to claim 2, wherein the second dielectric material is deposited in such a manner that airgaps are created between adjacent conductive lines.

4. The method according to claim 3, wherein an airgap is formed on each side of the conductive line on top of which the interconnect via is formed, and wherein the two airgaps have a top portion that overlaps a lower portion of the height of the interconnect via.

5. The method according to claim 4, wherein the height of the top portion of the two airgaps is at least 50% of the height of the interconnect via.

6. The method according to claim 1, wherein the interconnect via has nano-sized dimensions in three orthogonal directions.

7. The method according to claim 6, wherein the height of the interconnect via is between 10 nm and 30 nm.

8. The method according to claim 1, wherein the opening is filled by a bottom-up fill technique and wherein the step of planarizing the surface of the dielectric layer is done without a CMP (chemical mechanical polishing) step.

9. The method according claim 1, wherein the first and second conductive material are chosen from the group consisting of Ru, W, and Mo.

10. The method according claim 1, wherein the first and second dielectric material is SiO₂ or a low-K material.

11. The method according to claim 1, wherein an adhesion layer is produced on the substrate prior to forming the layer of the first conductive material, or wherein an adhesion layer is produced on the layer of the first conductive material, prior to forming the dielectric layer.

12. An interconnect via for connecting a lower electrically conductive line in a first level of a multi-level interconnect structure to an upper electrically conductive line in a second level overlying the first level, the interconnect via comprising:
a substrate having an upper surface formed of a dielectric material with electrical conductors or contacts embedded in the dielectric material;
a layer of a first conductive material and a dielectric layer formed of a first dielectric material, on the layer of the first conductive material;
a conductive via embedded in the dielectric layer, wherein the upper surface of the via is coplanar with the upper surface of the dielectric layer, the upper surfaces forming a planarized surface;
a second dielectric material formed as to produce a planar surface; and
a conductive line, wherein an interconnect via is formed on the conductive line by removing the shoulders of the via, so that the width of the interconnect via is aligned to the width of the conductive line and coplanar with the planar surface of the second dielectric material.

13. The interconnect via according to claim 12, wherein the second dielectric material is deposited in such a manner that airgaps are created between adjacent conductive lines.

14. The interconnect via according to claim 12, further comprising:
an airgap formed on each side of the conductive line on top of which the interconnect via is formed, and wherein the two airgaps have a top portion that overlaps a lower portion of the height of the interconnect via.

15. The interconnect via according to claim 14, wherein the two airgaps are directly adjacent to the interconnect via.

16. The interconnect via according to claim 14, wherein the height of the top portion of the two airgaps is at least 50% of the height of the interconnect via.

17. The interconnect via according to claim 12, wherein the interconnect via has nano-sized dimensions in three orthogonal directions.

18. The interconnect via according to claim 12, wherein the height of the interconnect via is between 10 nm and 30 nm.

19. The interconnect via according to claim 12, wherein the first and second conductive material are chosen from the group consisting of Ru, W, and Mo.

20. The interconnect via according to claim 12, wherein the first and second dielectric material is SiO₂ or a low-K material.
